(19) United States
(12) Patent Application Publication
(10) Pub. No.: US 2025/0380464 A1
(43) Pub. Date: Dec. 11, 2025

(54) THIN FILM TRANSISTOR, DISPLAY DEVICE INCLUDING THE THIN FILM TRANSISTOR, AND ELECTRONIC DEVICE

(71) Applicant: Samsung Display Co., LTD., Yongin-si (KR)

(72) Inventors: Jong Woo JIN, Yongin-si (KR); Hyun Mo LEE, Yongin-si (KR); Yeon Hong KIM, Yongin-si (KR); Jun Hyung LIM, Yongin-si (KR)

(73) Assignee: Samsung Display Co., LTD., Yongin-si (KR)

(21) Appl. No.: 19/065,571

(22) Filed: Feb. 27, 2025

(30) Foreign Application Priority Data
Jun. 7, 2024 (KR) 10-2024-0074415

(51) Int. Cl. H10D 30/67; H01L 25/16; H10D 30/01; H10H 29/39

(52) U.S. Cl. CPC H10D 30/6758; H01L 25/167; H10D 30/031; H10H 29/39

(57) ABSTRACT

A thin film transistor included in a display device includes buffer layers on a substrate, an active pattern on the buffer layers, a gate electrode on the active pattern, a gate insulating layer between the active pattern and the gate electrode, and a source electrode and a drain electrode electrically connected to the active pattern and spaced apart in a first direction or a second direction crossing the first direction. The buffer layers include a first buffer layer contacting the active pattern, and a second buffer layer between the substrate and the first buffer layer, the first buffer layer has a first thickness in a third direction perpendicular to the first and second directions, the second buffer layer has a second thickness greater than the first thickness in the third direction, the first buffer layer includes silicon oxide (SiOₓ), and the second buffer layer does not include the silicon oxide.

### CROSS-REFERENCE TO RELATED APPLICATION(S)

This application claims priority to and benefits of Korean Patent Application No. 10-2024-0074415 under 35 U.S.C. § 119, filed on Jun. 7, 2024, in the Korean Intellectual Property Office, the entire contents of which are incorporated herein by references.

### BACKGROUND

### 1. Technical Field

The disclosure relates to a thin film transistor, a display device including the thin film transistor, and an electronic device.

### 2. Description of the Related Art

Recently, as interest in an information display is increased, research and development on a display device is continuously being conducted. In particular, an oxide thin film transistor is attracting attention as a thin film transistor applied to the display device.

The oxide thin film transistor has an advantage that mobility is higher than that of an amorphous silicon thin film transistor and large area application is easy through a low-temperature process compared to a poly-silicon thin film transistor. However, in case that the oxide thin film transistor implements high-resolution, low-power driving by reducing a channel length, a threshold voltage may move in a negative direction, and thus a driving problem may occur. In case that the oxide thin film transistor is used as a driving transistor that expresses a grayscale in a pixel, a disadvantage that expressing the grayscale is difficult because a driving voltage range (driving range) is narrow.

The content described above is only intended to help understanding of the background technology of the technical ideas of the disclosure, and therefore, it cannot be understood as content corresponding to prior art known to those skilled in the art of the disclosure.

### SUMMARY

Embodiments of the disclosure are to provide a thin film transistor with improved quality. For example, the thin film transistor may prevent a reduction in a driving voltage range by thinly disposing a buffer layer including silicon oxide.

Other embodiments of the disclosure to provide a method of manufacturing a thin film transistor with improved quality.

Still other embodiments of the disclosure are to provide a display device including a thin film transistor with improved quality.

According to an embodiment of the disclosure, a thin film transistor included in a display device includes buffer layers disposed on a substrate, an active pattern disposed on the buffer layers, a gate electrode disposed on the active pattern, a gate insulating layer disposed between the active pattern and the gate electrode, and a source electrode and a drain electrode electrically connected to the active pattern and spaced apart from each other in a first direction or a second direction crossing the first direction. The buffer layers include a first buffer layer contacting the active pattern, and a second buffer layer disposed between the substrate and the first buffer layer, the first buffer layer has a first thickness in a third direction perpendicular to the first and second directions, the second buffer layer has a second thickness greater than the first thickness in the third direction, the first buffer layer includes silicon oxide (SiOₓ), and the second buffer layer does not include the silicon oxide.

The first thickness may be about 100 nm or less.

The second buffer layer may include silicon nitride (SiNₓ).

The second buffer layer may have a dielectric constant of about 6 or more.

The buffer layers may have a first capacitance per unit area, the gate insulating layer may have a second capacitance per unit area, and the first capacitance may be about 60% or more of the second capacitance.

The buffer layers may have a first capacitance per unit area, and the first capacitance may be about 1.7×10⁻⁸ F/cm² or more.

The thin film transistor may further include a lower conductive layer disposed on the substrate and overlapping the active pattern, and a sum of the first thickness and the second thickness is more than about ½ of a thickness of the lower conductive layer.

The first thickness of the first buffer layer may be less than about ⅓ of the thickness of the lower conductive layer.

The buffer layers may further include a third buffer layer disposed between the substrate and the second buffer layer.

The first buffer layer may have a lower surface contacting the second buffer layer and an upper surface opposite to the lower surface and contacting the active pattern, and the upper surface of the first buffer layer and the active pattern have a same width.

The thin film transistor may further include a plurality of insulating layers disposed on the gate electrode, and the source electrode and the drain electrode may be disposed in a same layer on the plurality of insulating layers.

The active pattern may include a source area, a drain area, and a channel area disposed between the source area and the drain area, the source electrode may be electrically connected to the source area, and the drain electrode may be electrically connected to the drain area.

The thin film transistor may further include a lower conductive layer disposed on the substrate and overlapping the active pattern, and the lower conductive layer and the source electrode are electrically connected to each other to have a same voltage.

According to an embodiment of the disclosure, a method of manufacturing a thin film transistor includes forming a first buffer layer on a substrate, forming a second buffer layer on the first buffer layer, forming an active pattern on the first and second buffer layers, forming a gate insulating layer on the active pattern, forming a gate electrode overlapping the active pattern on the gate insulating layer, and forming a source electrode and a drain electrode electrically connected to the active pattern and spaced apart from each other in a first direction or a second direction crossing the first direction. The first buffer layer contacts the active pattern, the second buffer layer is disposed between the substrate and the first buffer layer, the first buffer layer has a first thickness in a third direction perpendicular to the first and second directions, and the second buffer layer has a second thickness greater than the first thickness in the third direction, the first buffer layer includes silicon oxide (SiOₓ), and the second buffer layer does not include the silicon oxide.

According to another embodiment of the disclosure, a display device includes a display element, and a thin film transistor providing a driving signal to the display element. The thin film transistor includes buffer layers disposed on a substrate, an active pattern disposed on the buffer layers, a gate electrode disposed on the active pattern, a gate insulating layer disposed between the active pattern and the gate electrode, and a source electrode and a drain electrode electrically connected to the active pattern and spaced apart from each other in a first direction or a second direction crossing the first direction. The buffer layers include a first buffer layer contacting the active pattern, and a second buffer layer disposed between the substrate and the first buffer layer, the first buffer layer has a first thickness in a third direction perpendicular to the first and second directions, the second buffer layer has a second thickness greater than the first thickness in the third direction, the first buffer layer includes silicon oxide (SiOₓ), and the second buffer layer does not include the silicon oxide.

The first thickness may be about 100 nm or less.

The second buffer layer may include silicon nitride (SiNₓ).

The display element may include an anode electrode connected to the thin film transistor, a light emitting layer disposed on the anode electrode, and a cathode electrode disposed on the light emitting layer disposed between the cathode electrode and the anode electrode.

An electronic device includes a processor to provide input image data and a display device to display an image based on the input image data, the display device including a thin film transistor, wherein the thin film transistor includes buffer layers disposed on a substrate, an active pattern disposed on the buffer layers, a gate electrode disposed on the active pattern, a gate insulating layer disposed between the active pattern and the gate electrode and a source electrode and a drain electrode electrically connected to the active pattern and spaced apart from each other in a first direction or a second direction crossing the first direction, wherein the buffer layers include a first buffer layer contacting the active pattern and a second buffer layer disposed between the substrate and the first buffer layer, the first buffer layer has a first thickness in a third direction perpendicular to the first and second directions, the second buffer layer has a second thickness greater than the first thickness in the third direction, the first buffer layer includes silicon oxide (SiOx), and the second buffer layer does not include the silicon oxide.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram illustrating an embodiment of a display device of the disclosure;

FIG. 2 is a schematic block diagram illustrating an embodiment of one of sub-pixels of FIG. 1;

FIG. 3 is a schematic diagram of an equivalent circuit illustrating an embodiment of the sub-pixel of FIG. 2;

FIG. 4 is a schematic plan view illustrating an embodiment of a display panel of FIG. 1;

FIG. 5 is a schematic cross-sectional view illustrating an embodiment of the display panel of FIG. 1;

FIGS. 6 and 7 are schematic cross-sectional views taken along line I˜I′ of FIG. 4, according to an embodiment of the disclosure;

FIGS. 8 and 9 are enlarged schematic views illustrating a part A of FIG. 6;

FIG. 10 is another schematic cross-sectional view taken along line I˜I′ of FIG. 4 according to another embodiment of the disclosure;

FIG. 11 is a schematic plan view illustrating an embodiment of a thin film transistor of the disclosure; and

FIGS. 12 to 18 are schematic cross-sectional views illustrating a method of manufacturing a thin film transistor according to an embodiment of the disclosure taken along line II˜II′ of FIG. 11.

FIG. 19 is a schematic block diagram of an electronic device according to an embodiment.

FIG. 20 shows schematic views of various embodiments of an electronic device.

### DETAILED DESCRIPTION OF THE EMBODIMENTS

Hereinafter, a preferred embodiment according to the disclosure is described in detail with reference to the accompanying drawings. It should be noted that in the following description, only portions necessary for understanding an operation according to the disclosure are described, and descriptions of other portions are omitted in order not to obscure the subject matter of the disclosure. The disclosure may be embodied in other forms without being limited to the embodiment described herein. However, the embodiment described herein is provided to describe in detail enough to easily implement the technical spirit of the disclosure to those skilled in the art to which the disclosure belongs.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the disclosure. Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing a relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in an embodiment, the term “under” may include both directions of on and under. The device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

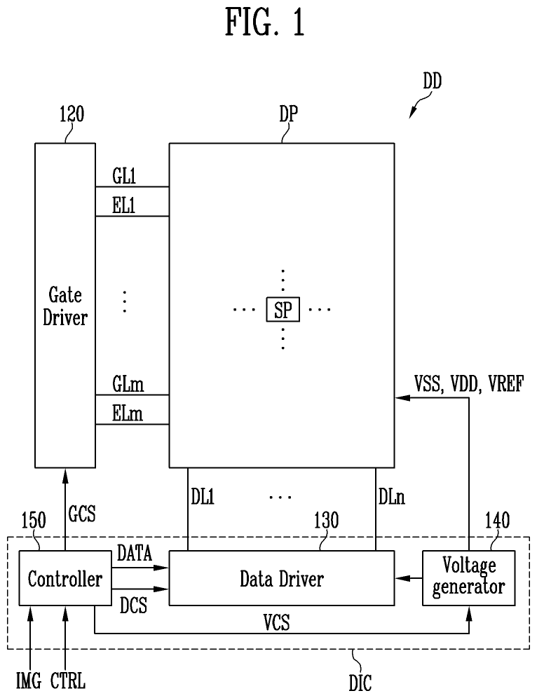

FIG. 1 is a schematic block diagram illustrating an embodiment of a display device of the disclosure.

Referring to FIG. 1, the display device DD may include a display panel DP, a gate driver 120, a data driver 130, a voltage generator 140, and a controller 150.

The display panel DP may include sub-pixels SP. The sub-pixels SP may be electrically connected to the gate driver 120 through first to m-th gate lines GL1 to GLm. The sub-pixels SP may be electrically connected to the data driver 130 through first to n-th data lines DL1 to DLn.

Each of the sub-pixels SP may include at least one light emitting element to generate light. Accordingly, each of the sub-pixels SP may generate light of a specific color such as red, green, blue, cyan, magenta, or yellow. Two or more sub-pixels among the sub-pixels SP may configure one pixel PXL. For example, three sub-pixels may configure one pixel PXL.

The gate driver 120 may be electrically connected to the sub-pixels SP arranged in a row direction through the first to m-th gate lines GL1 to GLm. The gate driver 120 may output gate signals to the first to m-th gate lines GL1 to GLm in response to a gate control signal GCS. The gate control signal GCS may include a start signal indicating a start of each frame, a horizontal synchronization signal for outputting the gate signals in synchronization with a timing at which data signals are applied, and the like.

First to m-th emission control lines EL1 to ELm connected to the sub-pixels SP of the row direction may be further provided. The gate driver 120 may include an emission control driver to control the first to m-th emission control lines EL1 to ELm, and the emission control driver may operate under control of the controller 150.

The gate driver 120 may be disposed on one side of the display panel DP. However, embodiments are not limited thereto. For example, the gate driver 120 may be divided into two or more physically and/or logically divided drivers, and such drivers may be disposed on one side of the display panel DP and another side of the display panel DP opposite the one side. As described above, the gate driver 120 may be disposed around the display panel DP in various shapes according to embodiments.

The data driver 130 may be electrically connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. The data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages from the voltage generator 140. In case that the gate signal is applied to each of the first to m-th gate lines GL1 to GLm, the data signals corresponding to the image data DATA may be applied to the data lines DL1 to DLn. Accordingly, the corresponding sub-pixels SP may generate light corresponding to the data signals. Accordingly, an image may be displayed on the display panel DP.

The gate driver 120 and the data driver 130 may include complementary metal-oxide semiconductor (CMOS) circuit elements.

The voltage generator 140 may operate in response to a voltage control signal VCS from the controller 150. The voltage generator 140 may generate multiple voltages and provide the generated voltages to components of the display device DD. For example, the voltage generator 140 may generate multiple voltages by receiving an input voltage from an outside of the display device DD, adjusting the received voltage, and regulating the adjusted voltage.

The voltage generator 140 may generate a first power voltage VDD and a second power voltage VSS. The generated first power voltage VDD and second power voltage VSS may be provided to the sub-pixels SP. The first power voltage VDD may have a relatively high voltage level, and the second power voltage VSS may have a voltage level lower than that of the first power voltage VDD. In other embodiments, the first power voltage VDD or the second power voltage VSS may be provided by an external device of the display device DD.

The voltage generator 140 may generate various voltages. For example, the voltage generator 140 may generate an initialization voltage applied to the sub-pixels SP. For example, during a sensing operation for sensing electrical characteristics of transistors and/or light emitting elements of the sub-pixels SP, a predetermined reference voltage VREF may be applied to the first to n-th data lines DL1 to DLn, and the voltage generator 140 may generate such a reference voltage VREF.

The controller 150 may control overall operations of the display device DD. The controller 150 may receive input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device DD or the display panel DP and output the image data DATA. The controller 150 may output the image data DATA by aligning the input image data IMG so that the input image data IMG is suitable for the sub-pixels SP of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. For example, the data driver 130, the voltage generator 140, and the controller 150 may be functionally divided components in one driver integrated circuit DIC. In other embodiments, at least one of the data driver 130, the voltage generator 140, and the controller 150 may be provided as a component distinguished from the driver integrated circuit DIC.

The controller 150 may control various operations of the display device DD. For example, the controller 150 may control the data signals and the first and second power voltages VDD and VSS by controlling components such as the data driver 130 and/or the voltage generator 140.

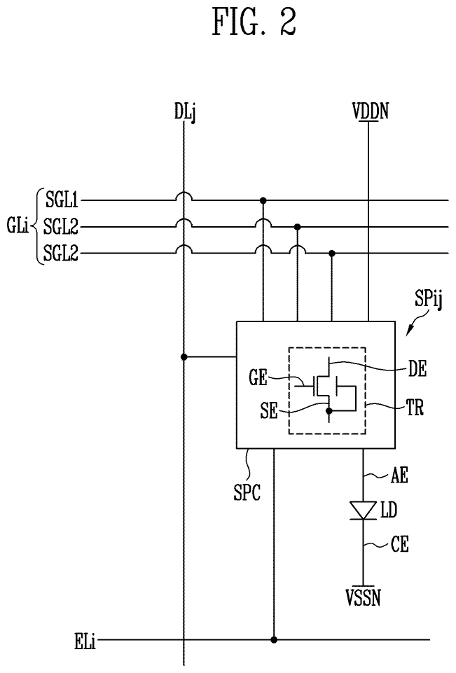

FIG. 2 is a schematic block diagram illustrating an example of any one of the sub-pixels of FIG. 1. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD may be electrically connected between a first power voltage node VDDN and a second power voltage node VSSN. At this time, the first power voltage node VDDN may be a node that transmits the first power voltage VDD of FIG. 1, and the second power voltage node VSSN may be a node that transmits the second power voltage VSS of FIG. 1.

An anode electrode AE of the light emitting element LD may be electrically connected to the first power voltage node VDDN through the sub-pixel circuit SPC, and a cathode electrode CE of the light emitting element LD may be electrically connected to the second power voltage node VSSN. For example, the anode electrode AE of the light emitting element LD may be electrically connected to the first power voltage node VDDN through at least one transistor TR included in the sub-pixel circuit SPC. Accordingly, a current may flow from the first power voltage node VDDN to the second power voltage node VSSN. The light emitting element LD may emit light according to an amount of the flowing current.

The sub-pixel circuit SPC may be electrically connected to an i-th gate line GLi among the first to m-th gate lines GL1 to GLm of FIG. 1, an i-th emission control line ELi among the first to m-th emission control lines EL1 to ELm of FIG. 1, and a j-th data line DLj among the first to n-th data lines DL1 to DLn of FIG. 1. The sub-pixel circuit SPC may control the light emitting element LD according to signals received through such signal lines.

The sub-pixel circuit SPC may operate in response to a gate signal received through the i-th gate line GLi. The i-th gate line GLi may include one or more sub gate lines. As shown in FIG. 2, the i-th gate line GLi may include first and second sub gate lines SGL1 and SGL2. The sub-pixel circuit SPC may operate in response to gate signals received through the first and second sub gate lines SGL1 and SGL2. As described above, in case that the i-th gate line GLi includes two or more sub gate lines, the sub-pixel circuit SPC may operate in response to gate signals received through the corresponding sub gate lines.

The sub-pixel circuit SPC may operate in response to an emission control signal received through the i-th emission control line ELi. The i-th emission control line ELi may include one or more sub emission control lines. In case that the i-th emission control line ELi includes two or more sub emission control lines, the sub-pixel circuit SPC may operate in response to emission control signals received through the corresponding sub emission control lines.

The sub-pixel circuit SPC may receive a data signal through the j-th data line DLj. The sub-pixel circuit SPC may store a voltage corresponding to the data signal in response to at least one of the gate signals received through the first and second sub gate lines SGL1 and SGL2. The sub-pixel circuit SPC may adjust a current flowing from the first power voltage node VDDN to the second power voltage node VSSN through the light emitting element LD according to the stored voltage, in response the emission control signal received through the i-th emission control line ELi. Accordingly, the light emitting element LD may generate light of a luminance corresponding to the data signal.

The sub-pixel circuit SPC may include multiple transistors. In FIG. 2, one transistor TR among multiple transistors of the sub-pixel circuit SPC is shown. As an example, the transistor TR may be a thin film transistor (TFT). The transistor TR may include a first electrode (or a drain electrode DE), a second electrode (or a source electrode SE), and a gate electrode GE.

The first electrode DE (or a drain electrode DE) of the transistor TR may be electrically connected to the first power voltage node VDDN. The second electrode SE (or a source electrode SE) of the transistor TR may be electrically connected to the anode electrode AE of the light emitting element LD. The gate electrode GE of the transistor TR may be electrically connected to the j-th data line DLj. The transistor TR is a driving transistor that controls a current flowing from the first power voltage node VDDN to the second power voltage node VSSN via the light emitting element LD in response to a voltage of the j-th data line DLj.

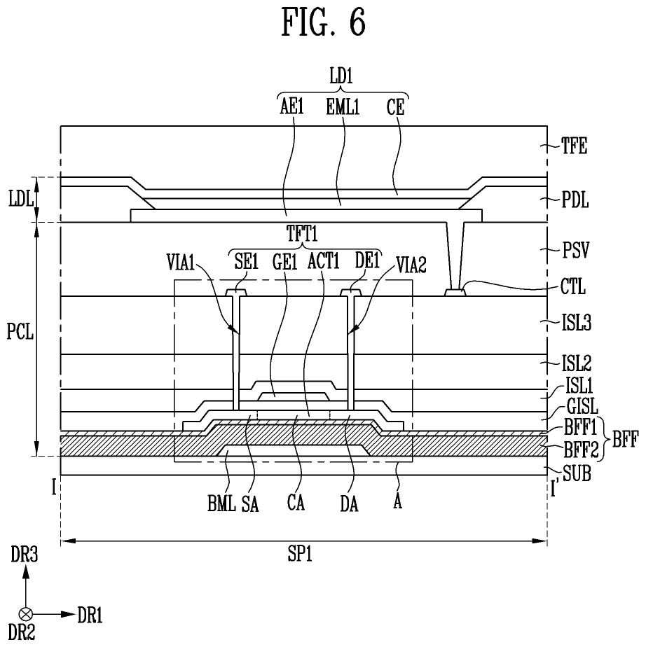

The transistor TR may further include a lower conductive layer BML (refer to FIG. 6) facing the gate electrode GE with a gate insulating layer GISL (refer to FIG. 6) interposed therebetween. The lower conductive layer BML may be electrically connected to the second electrode SE (or a source electrode SE), and thus the same voltage may be applied to the lower conductive layer BML and the second electrode SE (or a source electrode SE).

In FIG. 2, the transistor TR is shown as an N-type transistor, but is not limited thereto. For example, the transistor TR may be a P-type transistor. The first electrode DE and the second electrode SE (or a source electrode SE) of the transistor TR may be changed according to a direction of a voltage applied to the transistor TR and/or a type of the transistor TR.

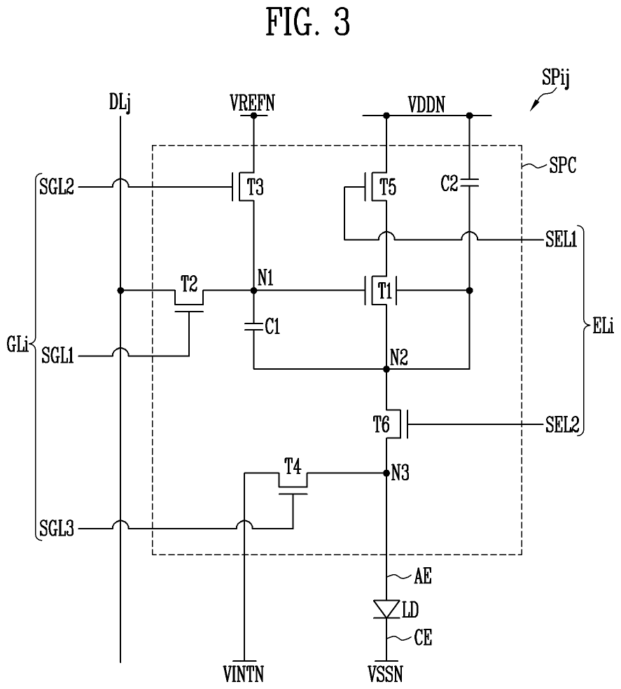

FIG. 3 is a schematic diagram of an equivalent circuit illustrating an embodiment of the sub-pixel of FIG. 2.

Referring to FIG. 3, the sub-pixel SPij may include a sub-pixel circuit SPC and a light emitting element LD.

The sub-pixel circuit SPC may be electrically connected to an i-th gate line GLi, an i-th emission control line ELi, and a j-th data line DLj. The i-th gate line GLi may include first to third sub gate lines SGL1 to SLG3. The i-th emission control line ELi may include first and second sub emission control lines SEL1 and SEL2.

The sub-pixel circuit SPC may include first to sixth transistors T1 to T6 and first and second capacitors C1 and C2. A thin film transistor according to an embodiment of the disclosure may be applied to at least one of the first to sixth transistors T1 to T6.

The first transistor T1 may be electrically connected between the first power voltage node VDDN and a second node N2. The first transistor T1 may be provided as the transistor TR of FIG. 2. The first electrode DE (refer to FIG. 2) of the first transistor T1 may be electrically connected to the fifth transistor T5, and the second electrode SE (refer to FIG. 2) of the first transistor T1 may be electrically connected to the second node N2. The gate electrode GE (refer to FIG. 2) of the first transistor T1 may be electrically connected to a first node N1, and thus the first transistor T1 may be turned on according to a voltage level of the first node N1. The first transistor T1 may control an amount of a driving current flowing from the first power voltage node VDDN to the second power voltage node VSSN. Therefore, the first transistor T1 may be referred to as a driving transistor.

The second transistor T2 may have a gate electrode connected to the first sub gate line SGL1, a first electrode connected to the j-th data line DLj, and a second electrode connected to the first node N1. The second transistor T2 may transmit a data voltage applied to the j-th data line DLj to the first node N1 in response to a signal of the first sub gate line SGL1. Therefore, the second transistor T2 may be referred to as a data write transistor.

The third transistor T3 may have a gate electrode electrically connected to the second sub gate line SGL2, a first electrode electrically connected to a reference voltage node VREFN, and a second electrode electrically connected to the first node N1. The reference voltage VREF (refer to FIG. 1) may be supplied through the reference voltage node VREFN. The third transistor T3 may apply the reference voltage VREF to the first node N1 in response to a signal of the second sub gate line SGL2, to initialize a voltage of the first node N1 to the reference voltage VREF. Therefore, the third transistor T3 may be referred to as a first initialization transistor.

The fourth transistor T4 may have a gate electrode GE electrically connected to the third sub gate line SGL3, a first electrode electrically connected to an initialization voltage node VINTN, and a second electrode electrically connected to a third node N3. The initialization voltage may be supplied through the initialization voltage node VINTN. The fourth transistor T4 may apply the initialization voltage to the third node N3 in response to a signal of the third sub gate line SGL3, to initialize a voltage of the third node N3 to the initialization voltage. Therefore, the fourth transistor T4 may be referred to as a second initialization transistor.

The fifth transistor T5 may have a gate electrode electrically connected to the first sub emission control line SEL1, a first electrode electrically connected to the first power voltage node VDDN, and a second electrode electrically connected to the first transistor T1. The fifth transistor T5 may control opening and closing (or disconnecting and connecting) of a driving current path electrically connected from the first power voltage node VDDN to the second power voltage node VSSN in response to a signal of the first sub emission control line SEL1. Therefore, the fifth transistor T5 may be referred to as a first emission control transistor.

The sixth transistor T6 may have a gate electrode electrically connected to the second sub emission control line SEL2, a first electrode electrically connected to the second node N2, and a second electrode electrically connected to the third node N3. The sixth transistor T6 may control opening and closing of the driving current path electrically connected from the first power voltage node VDDN to the second power voltage node VSSN in response to a signal of the second sub emission control line SEL2. Therefore, the sixth transistor T6 may be referred to as a second emission control transistor.

The first capacitor C1 may be electrically connected to the first node N1 and the second node N2. The second capacitor C2 may be electrically connected to the first power voltage node VDDN and the second node N2.

As described above, the sub-pixel circuit SPC may include the first to sixth transistors T1 to T6 and the first and second capacitors C1 and C2. However, embodiments are not limited thereto. The sub-pixel circuit SPC may be implemented as one of various types of circuits including multiple transistors and at least one capacitor. For example, the sub-pixel circuit SPC may include two transistors and one capacitor. According to embodiments of the sub-pixel circuit SPC, the number of sub gate lines included in the i-th gate line GLi and the number of sub emission control lines included in the i-th emission control line ELi may be varied.

The first to sixth transistors T1 to T6 may be N-type transistors. However, embodiments are not limited thereto. For example, at least one of the first to sixth transistors T1 to T6 may be replaced with a P-type transistor.

Each of the first to sixth transistors T1 to T6 may be an oxide thin film transistor. The oxide thin film transistor may be a low temperature polycrystalline oxide (LTPO) thin film transistor in which an active pattern (semiconductor layer) includes oxide. However, this is an example and is not limited thereto. For example, the active pattern (semiconductor layer) included in the N-type transistor may include an inorganic semiconductor (for example, amorphous silicon, poly silicon), an organic semiconductor, or the like.

The light emitting element LD may have the anode electrode AE electrically connected to the third node N3 and the cathode electrode CE electrically connected to the second power voltage node VSSN. The light emitting element LD may be a light emitting diode. However, embodiments are not limited thereto. For example, the light emitting element LD may be an organic light emitting diode, an inorganic light emitting diode, a quantum dot/well light emitting diode, or the like.

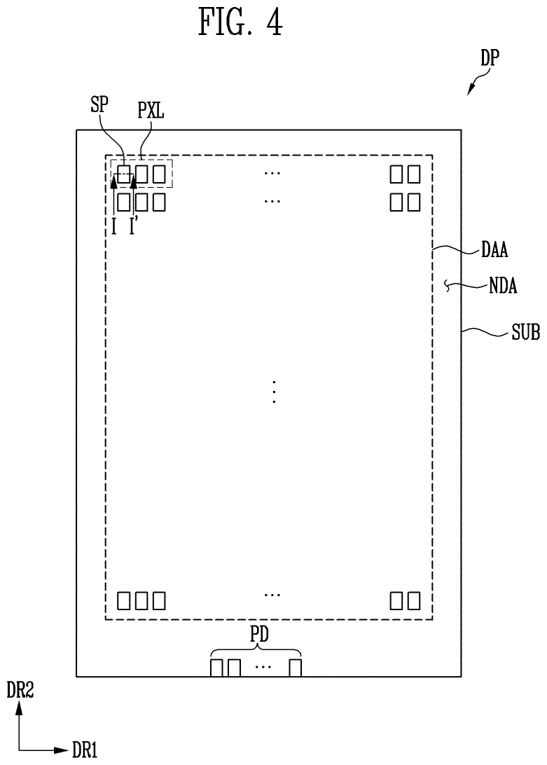

FIG. 4 is a schematic plan view illustrating an embodiment of the display panel of FIG. 1.

Referring to FIG. 4, an embodiment of the display panel DP of FIG. 1 may include a display area DAA and a non-display area NDA. The display panel DP may display an image (or images) through the display area DAA. The non-display area NDA may be disposed adjacent to the display area DAA. For example, the non-display area NDA may surround the display area DAA.

The display panel DP may include a substrate SUB, the sub-pixels SP, and pads PD.

The sub-pixels SP may be disposed in the display area DAA on the substrate SUB. The sub-pixels SP may be arranged in a matrix shape along a first direction DR1 and a second direction DR2 crossing the first direction DR1. However, embodiments are not limited thereto. For example, the sub-pixels SP may be arranged in a zigzag shape along the first direction DR1 and the second direction DR2. For example, the sub-pixels SP may be arranged in a Pentile® shape. The first direction DR1 may be a row direction, and the second direction DR2 may be a column direction.

Two or more sub-pixels among multiple sub-pixels SP may configure one pixel PXL. For example, three sub-pixels SP may configure one pixel PXL.

A component for controlling the sub-pixels SP may be disposed in the non-display area NDA on the substrate SUB. For example, lines electrically connected to the sub-pixels SP, such as the first to m-th gate lines GL1 to GLm and the first to n-th data lines DL1 to DLn of FIG. 1, may be disposed in the non-display area NDA.

At least one of the gate driver 120, the data driver 130, the voltage generator 140, and the controller 150 of FIG. 1 may be integrated in the non-display area NDA of the display panel DP. The gate driver 120 of FIG. 1 may be mounted on the display panel DP and may be disposed in the non-display area NDA. In other embodiments, the gate driver 120 may be implemented as an integrated circuit separated from the display panel DP.

The pads PD may be disposed in the non-display area NDA on the substrate SUB. The pads PD may be electrically connected to the sub-pixels SP through lines. For example, the pads PD may be electrically connected to the sub-pixels SP through the first to n-th data lines DL1 to DLn.

The pads PD may interface the display panel DP to other components of the display device DD (refer to FIG. 1). Voltages and signals for an operation of components included in the display panel DP may be provided from the driver integrated circuit DIC of FIG. 1 through the pads PD. For example, the first to n-th data lines DL1 to DLn may be electrically connected to the driver integrated circuit DIC through the pads PD. For example, the first and second power voltages VDD and VSS may be received from the driver integrated circuit DIC through the pads PD. For example, in case that the gate driver 120 is mounted on the display panel DP, the gate control signal GCS may be transmitted from the driver integrated circuit DIC to the gate driver 120 through the pads PD.

A circuit board may be electrically connected to the pads PD using a conductive adhesive member such as an anisotropic conductive film. The circuit board may be a flexible circuit board (FPCB) or a flexible film having a flexible material. The driver integrated circuit DIC may be mounted on the circuit board to be electrically connected to the pads PD.

The display area DAA may have various shapes. The display area DAA may have a closed loop shape including straight and/or curved sides. For example, the display area DAA may have shapes such as a polygon, a circle, a semicircle, and an ellipse.

The display panel DP may have a flat display surface. In other embodiments, the display panel DP may have a display surface that is at least partially round. The display panel DP may be bendable, foldable, or rollable. For example, the display panel DP and/or the substrate SUB may include materials having a flexible property.

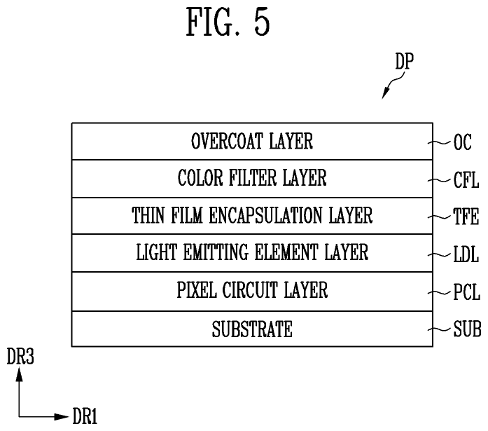

FIG. 5 is a schematic cross-sectional view illustrating an embodiment of the display panel of FIG. 1.

Referring to FIG. 5, the display panel DP may include a substrate SUB, a pixel circuit layer PCL, a light emitting element layer LDL, a thin film encapsulation layer TFE, a color filter layer CFL, and an overcoat layer OC.

The substrate SUB may include a semiconductor substrate. As an example, the substrate SUB may include a silicon bulk wafer or an epitaxial wafer. The epitaxial wafer may include a crystalline material layer, that is, an epitaxial layer, grown by an epitaxial process on a bulk substrate. The substrate SUB is not limited to the bulk wafer or the epitaxial wafer, and may be formed using various wafers such as a polished wafer, an annealed wafer, and silicon on insulator (SOI) wafer.

The pixel circuit layer PCL may be disposed on the substrate SUB and may include circuit elements of the sub-pixel circuit SPC (refer to FIG. 2) and at least one insulating layer positioned between the circuit elements. The circuit elements may include at least one transistor TR and signal lines connected to the at least one transistor TR.

The light emitting element layer LDL may include the light emitting element LD (refer to FIG. 2) and a pixel defining layer PDL (refer to FIG. 6). The light emitting element LD may be positioned in each of the sub-pixels SP. The light emitting element LD may include the anode electrode AE (refer to FIG. 2), a light emitting layer, and the cathode electrode CE (refer to FIG. 2) connected to at least one transistor TR.

The thin film encapsulation layer TFE may be disposed on the light emitting element layer LDL. The thin film encapsulation layer TFE may cover the light emitting element layer LDL and may prevent oxygen, moisture, and/or the like from penetrating into the light emitting element LD.

The color filter layer CFL may be disposed on the thin film encapsulation layer TFE. The color filter layer CFL may selectively transmit light emitted from the light emitting elements LD in an image display direction (or a front direction) of the display device DD, but is not limited thereto.

The overcoat layer OC may be disposed on the color filter layer CFL. The overcoat layer OC may cover lower members including the color filter layer CFL. The overcoat layer OC may protect the above-described lower members from a foreign substance such as dust.

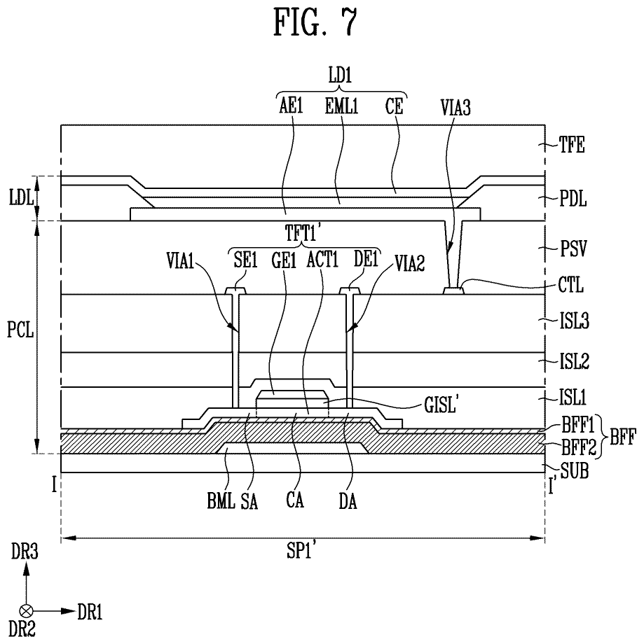

FIGS. 6 and 7 are schematic cross-sectional views taken along line I˜I′ of FIG. 4 according to an embodiment of the disclosure. A first thin film transistor TFT1 shown in FIG. 6 may be understood as one of the first to sixth transistors T1 to T6 of FIG. 3. Hereinafter, for convenience of description, it is assumed that the first thin film transistor TFT1 is the first transistor T1 of FIG. 3. However, embodiments are not limited thereto. For example, the first thin film transistor TFT1 may be one of the second to sixth transistors T2 to T6 of FIG. 3.

Referring to FIG. 6, the first thin film transistor TFT1 according to an embodiment of the disclosure may include a first active pattern ACT1 including an oxide semiconductor, and a first gate electrode GE1 insulated from the first active pattern ACT1. The first thin film transistor TFT1 may include a first source electrode SE1 and a first drain electrode DE1 connected to the first active pattern ACT1. The first thin film transistor TFT1 may function as a driving thin film transistor.

Hereinafter, a structure in which components included in the first thin film transistor TFT1 are stacked is described.

Buffer layers BFF may be disposed on the substrate SUB. The buffer layers BFF may reduce or block penetration of a foreign substance, moisture, or external air from a lower portion of the substrate SUB, and may provide a flat surface on the substrate SUB. The buffer layers BFF may have a multiple layer structure including a first buffer layer BFF1 and a second buffer layer BFF2, which are disposed between the substrate SUB and the first active pattern ACT1.

The first buffer layer BFF1 may contact the first active pattern ACT1. The first buffer layer BFF1 may include silicon oxide (SiOₓ). As an example, the first buffer layer BFF1 may be formed as a single layer including silicon oxide (SiOₓ). The first buffer layer BFF1 may be formed in a relatively thin thickness compared to the second buffer layer BFF2 disposed under the first buffer layer BFF1. The first buffer layer BFF1 may have a thickness of about 100 nm or less. In other embodiments, the first buffer layer BFF1 may have a thickness of about 20 nm or more and about 50 nm or less. The first buffer layer BFF1 may block diffusion of metal atoms or impurities from the substrate SUB and/or the lower conductive layer BML to an active pattern ACT to be formed later. As the thickness D1 of the first buffer layer BFF1 is decreased, a voltage applied to the lower conductive layer BML may have a greater influence on the active pattern ACT to be formed later. Accordingly, as the thickness D1 of the first buffer layer BFF1 is decreased, a current amount changing according to a gate voltage may decrease in the thin film transistor TFT, and thus a driving voltage range may be expanded.

The second buffer layer BFF2 may be disposed between the substrate SUB and the first buffer layer BFF1. The second buffer layer BFF2 may not include silicon oxide (SiOₓ). As an example, the second buffer layer BFF2 may include silicon nitride (SiNₓ). The second buffer layer BFF2 may be formed as a single layer or multiple layers including silicon nitride (SiNₓ). However, the second buffer layer BFF2 is not limited to silicon nitride (SiNₓ) unless the second buffer layer BFF2 is silicon oxide (SiOₓ). For example, the second buffer layer BFF2 may include silicon oxynitride (SiOₓN_{y}), aluminum oxide (Al₂O₃), titanium oxide (TiO₂), tantalum oxide (Ta₂O₅), hafnium oxide (HfO₂), zinc oxide (ZrO₂), or the like.

As another example, the second buffer layer BFF2 may include a material with a dielectric constant of about 6 or more. For example, in case that the first buffer layer BFF1 includes silicon dioxide (SiO₂) with a low dielectric constant (about 3.9), a strong electric field may be applied to the first buffer layer BFF1. On the other hand, in case that the second buffer layer BFF2 includes silicon nitride (Si₃N₄) with a relatively high dielectric constant (about 7.6), a low electric field may be applied. In case that a voltage is applied to the first buffer layer BFF1 and the second buffer layer BFF2, a voltage drop and an electric field distribution of each buffer layer may be formed differently due to a difference in a dielectric constant.

As described above, the buffer layers BFF may include the first buffer layer BFF1 including silicon oxide (SiOₓ), and the second buffer layer BFF2 that does not include silicon oxide (SiOₓ) under the first buffer layer BFF1. For example, by forming a thickness of the first buffer layer BFF1 to about 100 nm or less, a phenomenon in which a concentration of a threshold voltage moves in a negative direction as a channel length decreases may be prevented. As the thickness of the first buffer layer is decreased, a driving voltage range (DR range) may be expanded. Accordingly, a voltage difference between intermediate grayscale voltages may increase and a luminance difference of a grayscale image may become clearer, thereby improving display quality.

The first active pattern ACT1 may be disposed on the first buffer layer BFF1. The first active pattern ACT1 may include an oxide semiconductor (oxide) including at least one of indium (In), gallium (Ga), zinc (Zn), tin (Sn), hafnium (Hf), and titanium (Ti) and oxygen (O2). The first active pattern ACT1 may include a source area SA, a drain area DA, and a channel area CA disposed between the source area SA and the drain area DA. The source area SA and the drain area DA may be spaced apart from each other in the first direction DR1 or the second direction DR2 crossing the first direction DR1 with respect to the channel area CA interposed therebetween. The source area SA and the drain area DA of the first active pattern ACT1 may be formed to have conductivity by adjusting a carrier concentration of the oxide semiconductor.

The source area SA of the first active pattern ACT1 may be electrically connected to a first source electrode SE1 through a first via hole VIA1. The first via hole VIA1 may be a hole passing through the gate insulating layer GISL and first to third insulating layers ISL1 to ISL3 to expose the source area SA of the first active pattern ACT1. The drain area DA of the first active pattern ACT1 may be electrically connected to the first drain electrode DE1 through a second via hole VIA2. The second via hole VIA2 may be a hole passing the gate insulating layer GISL and the first to third insulating layers ISL1 to ISL3 to expose the drain area DA of the first active pattern ACT1.

The gate insulating layer GISL may be disposed on the first active pattern ACT1 to cover the first active pattern ACT1. The gate insulating layer GISL may have a single layer or multiple layer structure including an inorganic insulating material. For example, the inorganic insulating layer may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZnO₂), or the like.

The first gate electrode GE1 may overlap the first active pattern ACT1 on the gate insulating layer GISL in the third direction DR3. The first gate electrode GE1 may be insulated from the first active pattern ACT1 by the gate insulating layer GISL. The first gate electrode GE1 may have a single layer or multiple layer structure including copper (Cu) or a copper (Cu) alloy, but is not limited thereto. For example, the first gate electrode GE1 may include indium zinc oxide (InZnO), silver (Ag), zinc (Zn), magnesium (Mg), aluminum (Al), titanium (Ti), or the like.

The first gate electrode GE1 may have a width shorter than the entire width of the first active pattern ACT1 in the first direction DR1 and equal to a width of the channel area CA of the first active pattern ACT1. In FIG. 6, the width of the first gate electrode GE1 may be substantially equal to the channel area CA of the first active pattern ACT1, but is not limited thereto. For example, the first gate electrode GE1 may have a width longer than the width of the channel area CA of the first active pattern ACT1 in the first direction DR1.

The first insulating layer ISL1 may be disposed on the first gate electrode GE1. The first insulating layer ISL1 may be disposed to cover the first gate electrode GE1. The first insulating layer ISL1 may have a single layer or multiple layer structure including an inorganic insulating material. For example, the inorganic insulating material may include silicon oxide (SiOₓ), silicon nitride (SiNₓ), silicon oxynitride (SiOₓN_{y}), aluminum oxide (Al₂O₃), titanium oxide (TiO₂), or the like.

One or more insulating layers may be further disposed on the first insulating layer ISL1. In FIG. 6, the second and third insulating layers ISL2 and ISL3 are shown as being disposed on the first insulating layer ISL1. The second and third insulating layers ISL2 and ISL3 may include silicon oxide (SiOₓ), silicon nitride (SiNₓ), silicon oxynitride (SiOₓN_{y}), aluminum oxide (Al₂O₃), titanium oxide (TiO₂), or the like.

Conductive patterns may be disposed between the first to third insulating layers ISL1 to ISL3. The conductive patterns may include at least one of electrodes at both ends of the first and second capacitors C1 and C2 of FIG. 3. The conductive patterns may further include a source electrode and a drain electrode of at least one of the second to sixth transistors T2 to T6 of FIG. 3. The conductive patterns may include at least one of copper and a copper alloy, but embodiments are not limited thereto. For example, the conductive patterns may include indium zinc oxide (InZnO), silver (Ag), zinc (Zn), magnesium (Mg), aluminum (Al), titanium (Ti), and the like. An active pattern (or a semiconductor layer) of at least one of the second to sixth transistors T2 to T6 may be further disposed between the first insulating layer ISL1 and one or more insulating layers.

The first source electrode SE1 and the first drain electrode DE1 electrically connected to the first active pattern ACT1 may be disposed on the third insulating layer ISL3. A conductive layer CTL may be disposed on the third insulating layer ISL3. For example, the first source electrode SE1, the first drain electrode DE1, and the conductive layer CTL may be disposed in the same layer. The conductive layer CTL may be an electrode that electrically connects one of multiple transistors of the sub-pixel circuit SPC (refer to FIG. 3) to the anode electrode AE of the light emitting element LD. For example, the conductive layer CTL may be an electrode corresponding to a source electrode of the sixth transistor T6 described with reference to FIG. 3.

The first source electrode SE1, the first drain electrode DE1, and the conductive layer CTL may include a conductive material such as metal or conductive oxide. For example, the first source electrode SE1, the first drain electrode DE1, and the conductive layer CTL may have a single layer or multiple layer structure including molybdenum (Mo), aluminum (Al), chromium (Cr), gold (Au), titanium (Ti), nickel (Ni), neodymium (Nd), copper (Cu), and an alloy thereof.

Accordingly, the first thin film transistor TFT1 may include the first active pattern ACT1, the first gate electrode GE1, the first source electrode SE1, and the first drain electrode DE1. In FIG. 6, the first thin film transistor TFT1 may be shown as a coplanar thin film transistor having a top gate structure, but is not limited thereto. For example, the first thin film transistor TFT1 may have a bottom gate structure in which the first gate electrode GE1 is positioned under the first active pattern ACT1.

The lower conductive layer BML may be disposed between the substrate SUB and the buffer layers BFF. The lower conductive layer BML may be disposed to overlap the first thin film transistor TFT1. As an example, the lower conductive layer BML may be disposed adjacent to the substrate SUB and may be disposed under the first thin film transistor TFT1. The lower conductive layer BML may overlap the first active pattern ACT1 of the first thin film transistor TFT1. A constant voltage or signal may be applied to the lower conductive layer BML. For example, the lower conductive layer BML and the first source electrode SE1 of the first thin film transistor TFT1 may be electrically connected to each other to have a same voltage. The first thin film transistor TFT1 may be controlled by a voltage applied to the first gate electrode GE1. As another example, the same voltage may be applied to the first source electrode SE1 and the first gate electrode GE1 of the first thin film transistor TFT1. The first thin film transistor TFT1 may be controlled by the voltage applied to the lower conductive layer BML.

The lower conductive layer BML may include metal or a conductive material. For example, the lower conductive layer BML may have a single layer or multiple layer structure including molybdenum (Mo), aluminum (Al), copper (Cu), titanium (Ti), or the like. The lower conductive layer BML may include a transparent conductive material. For example, the lower conductive layer BML may include indium tin oxide (ITO), indium zinc oxide (IZO), zinc oxide (ZnO), indium oxide (In₂O₃), indium gallium oxide (IGO), aluminum zinc oxide (AZO), or the like.

A protective layer PSV may be disposed on the third insulating layer ISL3 to cover the first source electrode SE1, the first drain electrode DE1, and the conductive layer CTL of the first thin film transistor TFT1. The protective layer PSV may have a single layer or multiple layer structure including an inorganic insulating material. For example, the protective layer PSV may be a single layer of one of silicon oxide (SiOₓ), silicon nitride (SiNₓ), and silicon nitride oxide (SiOₓN_{y}), or may be a multiple layer structure in which two or more of these are alternately stacked.

A first light emitting element LD1 including a first anode electrode AE1, a first light emitting layer EML1, and a cathode electrode CE, and the pixel defining layer PDL may be disposed on the protective layer PSV.

The first anode electrode AE1 may be formed on the pixel circuit layer PCL of a first sub-pixel SP1. As an example, the first anode electrode AE1 may be formed on an insulating layer of the pixel circuit layer PCL having a flat surface through a photolithography process using a mask. The first anode electrode AE1 may be disposed to overlap the conductive layer CTL on the protective layer PSV, and may be electrically connected to a conductive layer CTL through a third via hole VIA3 formed in the protective layer PSV. For example, the first anode electrode AE1 may be electrically connected to a source electrode of the sixth transistor T6 and a source electrode of the fourth transistor T4 described with reference to FIG. 3.

The first anode electrode AE1 may include a conductive material having a reflectance so that light emitted from the first light emitting layer EML1 proceeds in the third direction (e.g., thickness direction). For example, the conductive material may include a metal or the like such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof.

The pixel defining layer PDL may be an organic insulating layer including an organic material. For example, the organic material may include acryl resin, epoxy resin, phenolic resin, polyamide resin, polyimide resin, and the like. According to an embodiment, the pixel defining layer PDL may include a light absorbing material or may be coated with a light absorbing material to serve to absorb light input from an outside. For example, the pixel defining layer PDL may include a carbon-based black pigment, but is not limited thereto.

The first light emitting layer EML1 may be disposed on the first anode electrode AE1 exposed by the pixel defining layer PDL. The cathode electrode CE may be disposed on the first light emitting layer EML1. The cathode electrode CE may be a thin metal layer having a thickness sufficient to transmit the light emitted from the first light emitting layer EML1. For example, the cathode electrode CE may include a metal material or a transparent conductive material to have a relatively thin thickness.

The thin film encapsulation layer TFE may be entirely formed on the cathode electrode CE. The thin film encapsulation layer TFE may prevent a foreign substance, moisture, or external air from penetrating into the first light emitting layer EML1 and the cathode electrode CE.

The embodiments of FIG. 7 may be described similarly to the embodiments of FIG. 6 except that a first sub-pixel SP1′ includes a gate insulating layer GISL′. An overlapping description with respect to the embodiments of FIG. 6 is omitted, and a point different from the embodiments described above is mainly described.

Referring to FIG. 7, a first thin film transistor TFT1′ may include a first active pattern ACT1, a first gate electrode GE1, a first source electrode SE1, and a first drain electrode DE1. The gate insulating layer GISL′ may be patterned to overlap a portion of the first active pattern ACT1 of a first thin film transistor TFT1′. An area where the gate insulating layer GISL′ and the first active pattern ACT1 overlap may be defined as the channel area CA. For example, a process of conduction through plasma treatment, impurity doping, or the like may be performed on the source area SA and the drain area DA. A portion of the first active pattern ACT1 overlapping the gate insulating layer GISL′ may not be exposed to plasma treatment or impurity doping and may have a property different from that of the source area SA and the drain area DA. In case that plasma treatment or impurity doping is performed on the first active pattern ACT1, the channel area CA where an impurity is not doped may be formed at a position overlapping the gate insulating layer GISL′, by using the first gate electrode GE1 positioned on the gate insulating layer GISL′ as a self-align mask. Each of the source area SA and the drain area DA of which an impurity is doped may be formed at a position that does not overlap the gate insulating layer GISL′ on both sides of the channel area CA.

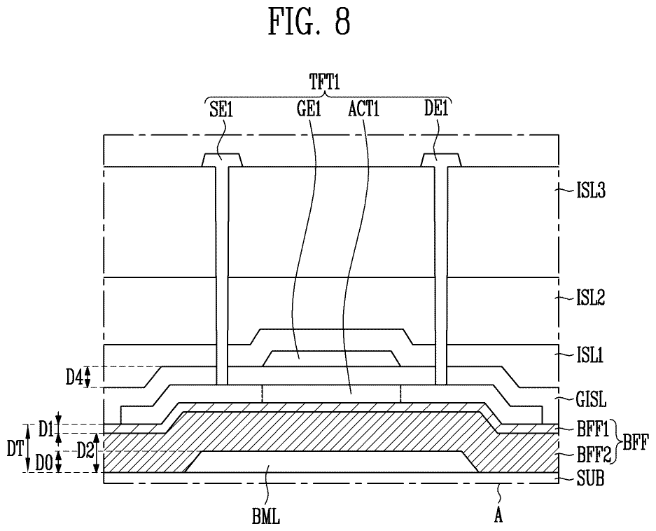

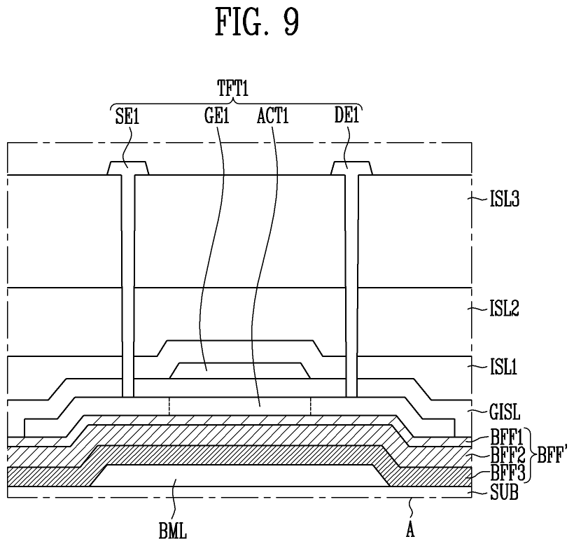

FIGS. 8 and 9 are enlarged schematic views illustrating a portion A of FIG. 6.

Referring to FIGS. 6 and 8, on the substrate SUB, the buffer layers BFF including the first buffer layer BFF1 including silicon oxide (SiOₓ) and the second buffer layer BFF2 that does not include silicon oxide (SiOₓ) may be disposed.

A total thickness DT of the buffer layers BFF may be a sum of a thickness D1 of the first buffer layer BFF1 and a thickness D2 of the second buffer layer BFF2. The total thickness DT of the buffer layers BFF may be about ½ or more of a thickness DO of the lower conductive layer BML disposed under the second buffer layer BFF2 and covered by the second buffer layer BFF2. For example, the total thickness DT of the buffer layers BFF may have an average thickness of about 200 nm or more. However, the corresponding thickness is an example and is not limited to the corresponding thickness in case that step coverage by the lower conductive layer BML may be improved.

The thickness D1 of the first buffer layer BFF1 may be about ⅓ or less of the thickness DO of the lower conductive layer BML, and may be relatively thinner than the thickness D2 of the second buffer layer BFF2. For example, the thickness D1 of the first buffer layer BFF1 may have an average thickness of about 100 nm or less. As another example, the thickness D1 of the first buffer layer BFF1 may have an average thickness of about 20 nm or more and about 50 nm or less. However, the corresponding thickness is an example, and is not limited to the corresponding thickness in case that the driving voltage range may be expanded.

The buffer layers BFF may have a capacitance per unit area (capacitance per area) of about 1.7×10⁻⁸ F/cm² or more. For example, in case that the thickness D1 of the first buffer layer BFF1 is about 100 nm and the thickness D2 of the second buffer layer BFF2 is about 200 nm, the buffer layers BFF have a capacitance per unit area of about 1.7×10⁻⁸ F/cm². These thicknesses may expand the driving voltage range by about 4% or more compared to a case where the thickness D1 of the first buffer layer BFF1 is about 160 nm and the thickness D2 of the second buffer layer BFF2 is about 200 nm. However, this is an example and is not limited thereto. For example, in case that the thickness D1 of the first buffer layer BFF1 is about 50 nm and the thickness D2 of the second buffer layer BFF2 is about 200 nm, the buffer layers BFF may have a capacitance per unit area of about 1.7×10⁻⁸ F/cm² or more.

The capacitance per unit area of the buffer layers BFF may be about 60% or more of a capacitance per unit area of the gate insulating layer GISL disposed on the buffer layers BFF and covering the first active pattern ACT1. For example, in case that a thickness D4 of the gate insulating layer GISL is about 140 nm, the thickness D1 of the first buffer layer BFF1 is about 100 nm, and the thickness D2 of the second buffer layer BFF2 is about 200 nm, the capacitance per unit area of the buffer layers BFF may be about 60% or more of the capacitance per unit area of the gate insulating layer GISL. As the capacitance per unit area of the gate insulating layer GISL decreases, an effect in which the driving voltage range is expanded by the buffer layers BFF may be increased. Alternatively, the thickness D4 of the gate insulating layer GISL increases, the effect in which the driving voltage range is expanded by the buffer layers BFF may be increased.

As described above, by adjusting the thickness of each of the first and second buffer layers BFF1 and BFF2, the capacitance per unit area of the buffer layers BFF may be formed to be about 1.7×10⁻⁸ F/cm² or more. In case that the capacitance per unit area of the buffer layers BFF is about 1.7×10⁻⁸ F/cm² or more, the driving voltage range may be expanded. As the thickness of each of the first and second buffer layers BFF1 and BFF2 and the thickness of the gate insulating layer GISL are changed, a ratio of the capacitance per unit area of the buffer layers BFF and the capacitance per unit area of the gate insulating layer GISL may be changed. By adjusting the thickness of the gate insulating layer GISL together with the first and second buffer layers BFF1 and BFF2, the driving voltage range may be further expanded.

Configurations of buffer layers BFF′ of FIG. 9 may be similarly configured to the embodiments of FIG. 8 described above except for a third buffer layer BFF3.

Referring to FIGS. 6 and 9, on the substrate SUB, buffer layers BFF′ including the first buffer layer BFF1 including silicon oxide (SiOₓ), the second buffer layer BFF2 that does not include silicon oxide (SiOₓ), and the third buffer layer BFF3 including silicon oxide (SiOₓ) may be disposed. As an example, the second buffer layer BFF2 may include silicon nitride (SiNₓ), and the third buffer layer BFF3 may include silicon oxide (SiOₓ). However, this is an example and is not limited thereto. For example, the second buffer layer BFF2 may include silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZrO₂), or the like except for silicon oxide (SiOₓ). On the other hand, the third buffer layer BFF3 may include silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZrO₂), or the like.

The first buffer layer BFF1 may be disposed to contact the first active pattern ACT1, and the second buffer layer BFF2 may be disposed between the substrate SUB and the first buffer layer BFF1. The third buffer layer BFF3 may be disposed between the substrate SUB and the second buffer layer BFF2. In FIG. 9, the buffer layers BFF′ may include the first to third buffer layers BFF1 to BFF3, but are not limited thereto. For example, the buffer layers BFF′ may include four or more buffer layers on the substrate SUB.

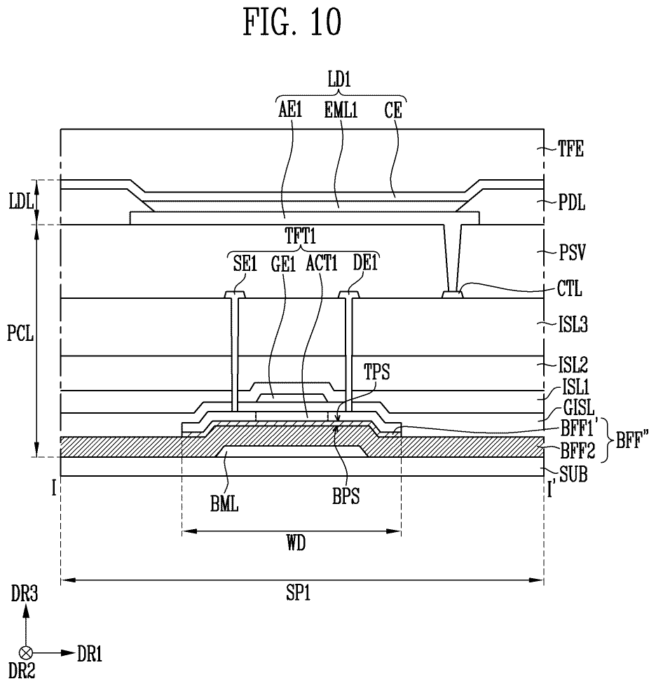

FIG. 10 is another schematic cross-sectional view taken along line I˜I′ of FIG. 4 according to another embodiment of the disclosure.

Referring to FIG. 10, the substrate SUB, the gate insulating layer GISL, the first to third insulating layers ISL1 to ISL3, the protective layer PSV, the pixel defining layer PDL, the thin film encapsulation layer TFE, the first thin film transistor TFT1, the conductive layer CTL, and the first light emitting element LD1 may be similarly described to the embodiment of FIG. 6. An overlapping description with respect to the embodiment of FIG. 6 is omitted, and a point different from the embodiment described above is mainly described.

Referring to FIG. 10, buffer layers BFF″ include a first buffer layer BFF1′ and the second buffer layer BFF2. The second buffer layer BFF2 is similarly described to the second buffer layer BFF2 of FIG. 6.

The first buffer layer BFF1′ may have the same width WD as the first active pattern ACT1 and may be disposed between the second buffer layer BFF2 and the first active pattern ACT1. As an example, the first buffer layer BFF1′ may have a lower surface BTS contacting the second buffer layer BFF2, and an upper surface TPS opposite to the lower surface BTS and contacting the first active pattern ACT1. The upper surface TPS of the first buffer layer BFF1′ may have the same width WD as the first active pattern ACT1 in the first direction DR1. However, the disclosure is not limited thereto, and the upper surface TPS of the first buffer layer BFF1′ may have a width greater than the width WD of the first active pattern ACT1 in the first direction DR1. The first buffer layer BFF1′ may not be entirely formed on the second buffer layer BFF2, and may be similarly patterned to a shape of the first active pattern ACT1. A portion of the second buffer layer BFF2 may not be covered by the first buffer layer BFF1′.

As described above, the first buffer layer BFF1′ may have a minimum area as long as the entire lower surface of the first active pattern ACT1 contacts the first buffer layer BFF1′ and is spaced apart from the second buffer layer BFF2.

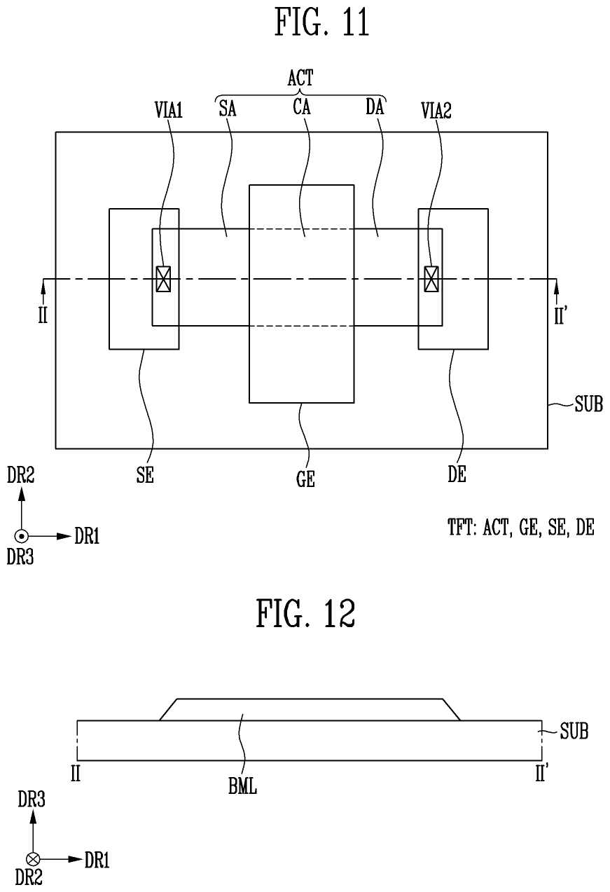

FIG. 11 is a schematic plan view illustrating an embodiment of a thin film transistor of the disclosure. The thin film transistor TFT of FIG. 11 may be provided as the transistor TR included in the sub-pixel circuit SPC of FIG. 2.

Referring to FIG. 11, the thin film transistor TFT according to an embodiment of the disclosure may include the gate electrode GE, an active pattern (or the semiconductor layer) ACT, the source electrode SE, and the drain electrode DE provided on the substrate SUB.

The substrate SUB may include an insulating material such as glass, organic polymer, and crystal. The substrate SUB may be formed of a material having flexibility so that bending or folding is possible, and may have a single layer structure or a multiple layer structure. For example, the substrate SUB may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, a material configuring the substrate SUB is not limited thereto and may be variously changed.

The buffer layers BFF (refer to FIG. 6) may be provided on the substrate SUB. The active pattern ACT may be provided on the buffer layers BFF. The active pattern ACT may include the source area SA, the drain area DA, and the channel area CA provided between the source area SA and the drain area DA. The active pattern ACT may be a semiconductor pattern including polysilicon, amorphous silicon, an oxide semiconductor, or the like. The channel area CA may be a semiconductor pattern that is not doped with an impurity and may be an intrinsic semiconductor. The source area SA and the drain area DA may be a semiconductor pattern doped with an impurity.

The gate insulating layer GISL (refer to FIG. 6) may be provided on the active pattern ACT. The gate electrode GE overlapping the channel area CA of the active pattern ACT may be provided on the gate insulating layer GISL. The gate electrode GE may be made of a conductive material, for example, a metal material. According to an embodiment, the gate electrode GE may be used as a doping protective layer that prevents an impurity from being doped into the active pattern ACT. Therefore, the gate electrode GE may define the channel area CA of the active pattern ACT.

Multiple insulating layers ISL2 to ISL3 (refer to FIG. 6) may be provided on the gate electrode GE. The source electrode SE and the drain electrode DE may be provided on multiple insulating layers ISL2 to ISL3.

The source electrode SE may be provided on the active pattern ACT to cover at least a portion of the active pattern ACT. The source electrode SE may be electrically connected to the source area SA through the first via hole VIA1 passing through the gate insulating layer GISL and multiple insulating layers ISL2 to ISL3.

The drain electrode DE may be provided on the active pattern ACT to cover at least a portion of the active pattern ACT. The drain electrode DE may be spaced apart from the source electrode SE at a certain distance in the first direction DR1. The drain electrode DE may be electrically connected to the drain area DA through the second via hole VIA2 passing through the gate insulating layer GISL and multiple insulating layers ISL2 to ISL3.

FIGS. 12 to 18 are schematic cross-sectional views illustrating a method of manufacturing a thin film transistor according to an embodiment of the disclosure according to line II˜II′ of FIG. 11.

Hereinafter, with reference to FIGS. 12 to 18, a method of manufacturing the thin film transistor described with reference to FIGS. 6, 8, and 11 is described. In case that describing FIGS. 12 to 18, a description of a content overlapping the content described with reference to FIGS. 6, 8, and 11 may be omitted.

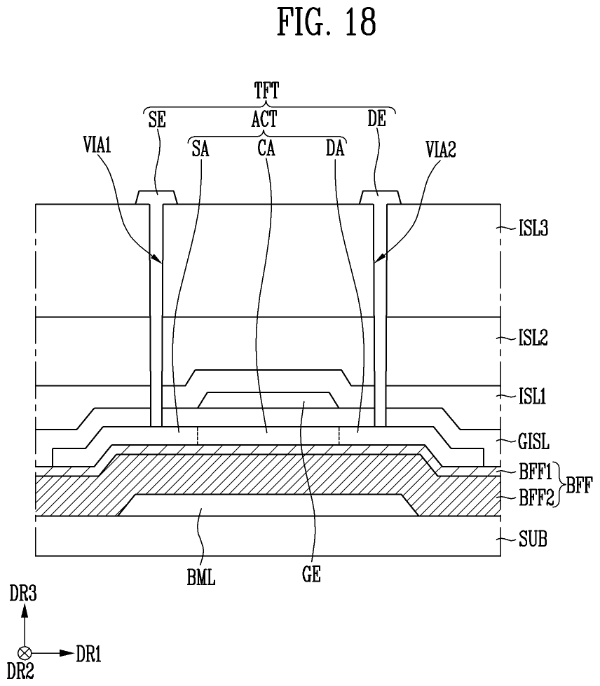

Referring to FIG. 12, the lower conductive layer BML may be formed on the substrate SUB. The lower conductive layer BML may be formed by depositing a conductive material on the substrate SUB and then patterning the conductive material through a process of photolithography or the like. In FIG. 12, the lower conductive layer BML may be shown as being disposed on the substrate SUB, but the lower conductive layer BML may be inserted into the substrate SUB. The lower conductive layer BML may be disposed under the thin film transistor TFT (refer to FIG. 18) to be formed later. For example, the lower conductive layer BML may be disposed between the substrate SUB and the thin film transistor TFT.

Referring to FIG. 13, the second buffer layer BFF2 may be formed on the substrate SUB to cover the lower conductive layer BML. The second buffer layer BFF2 may be formed by depositing silicon nitride (SiNₓ) on the entire surface of the substrate SUB. However, the second buffer layer BFF2 is not limited to silicon nitride (SiNₓ) unless the second buffer layer BFF2 is silicon oxide (SiOₓ). For example, the second buffer layer BFF2 may be formed by depositing a material having a dielectric constant of 6 or more.

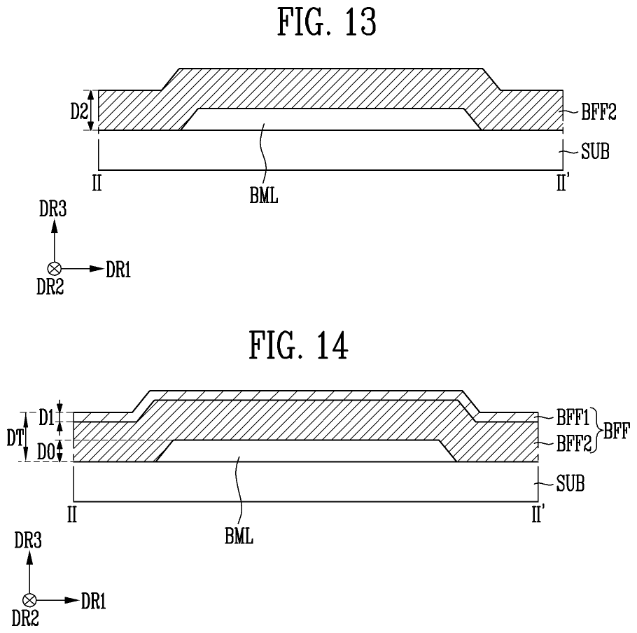

The second buffer layer BFF2 may be formed to have the thickness D2 greater than the thickness D1 (refer to FIG. 14) of the first buffer layer BFF1 (refer to FIG. 14) to be described later, thereby improving step coverage. For example, the second buffer layer BFF2 may be formed in the thickness D2 of about 200 nm or more on average to cover the lower conductive layer BML on the entire surface of the substrate SUB. However, the corresponding thickness is an example and is not limited thereto. Although only the second buffer layer BFF2 is shown in FIG. 13, multiple buffer layers may be further formed between the second buffer layer BFF2 and the substrate SUB.

Referring to FIG. 14, the first buffer layer BFF1 may be formed on the second buffer layer BFF2. The first buffer layer BFF1 may be formed by depositing silicon oxide (SiOₓ) on the entire surface of the second buffer layer BFF2. The first buffer layer BFF1 may be formed by depositing a material having a relatively low dielectric constant compared to the second buffer layer BFF2. Due to a difference in dielectric constant of the first buffer layer BFF1 and the second buffer layer BFF2, a voltage drop and an electric field distribution of each buffer layer may be differently formed.

The first buffer layer BFF1 may be formed to have the thickness D1 less than the thickness D2 of the second buffer layer BFF2 disposed under the first buffer layer BFF1. For example, the first buffer layer BFF1 may be formed in the thickness D1 of about 100 nm or less on average on the entire surface of the second buffer layer BFF2. As another example, the first buffer layer BFF1 may be formed in the thickness D1 of about 20 nm to about 50 nm on average on the entire surface of the second buffer layer BFF2. However, the corresponding thickness is an example and is not limited thereto. For example, the thickness D1 of the first buffer layer BFF1 may be formed in about ⅓ or less of the thickness DO of the lower conductive layer BML. The sum of the thickness D1 of the first buffer layer BFF1 and the thickness D2 of the second buffer layer BFF2 may be greater than about ½ or more of the thickness DO of the lower conductive layer BML.

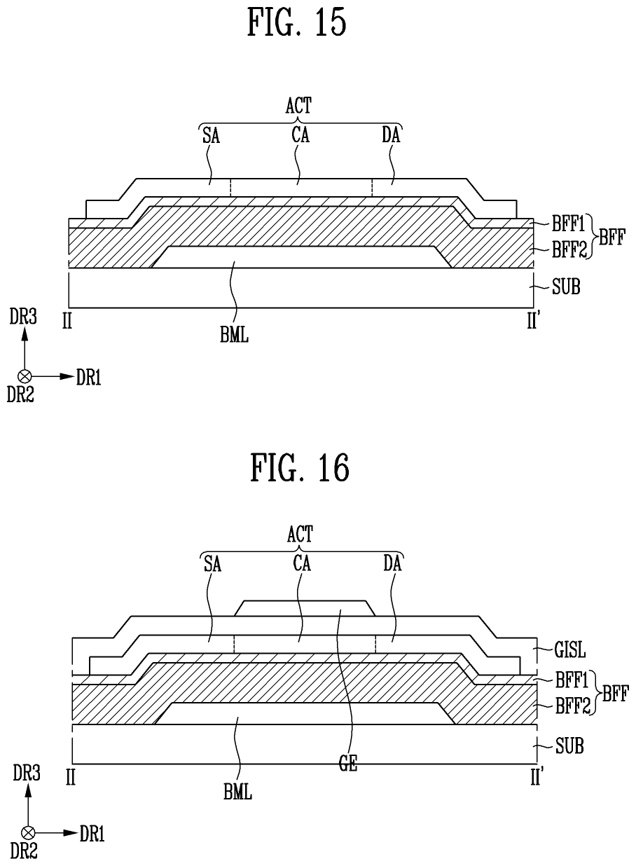

Referring to FIG. 15, the active pattern ACT may be formed on the first buffer layer BFF1. The active pattern ACT may be formed in a form of a thin film on the first buffer layer BFF1. The active pattern ACT may be formed to have conductivity by controlling a carrier concentration of the oxide semiconductor. For example, the channel area CA of the active pattern ACT may be formed as a semiconductor pattern that is not doped with an impurity. The source area SA and drain area DA of the active pattern ACT may be formed as a semiconductor pattern doped with an impurity. The impurity doped into the source area SA and the drain area DA may be an N-type impurity. For example, the N-type impurity may be a material such as phosphorus (P) ion. Alternatively, the impurity doped into the source area SA and the drain area DA may be a P-type impurity. For example, the P-type impurity may be a material such as boron (B) ion.

Referring to FIG. 16, the gate insulating layer GISL may be formed to cover the active pattern ACT on the first buffer layer BFF1 and the active pattern ACT. Thereafter, the gate electrode GE may be formed on the gate insulating layer GISL. For example, the gate electrode GE may be formed by depositing a conductive material on the gate insulating layer GISL and then patterning the conductive material through a process of photolithography or the like. The gate electrode GE may overlap the channel area CA of the active pattern ACT. The gate electrode GE may be formed at a position corresponding to the channel area CA of the active pattern ACT, and may have the same width as the channel area CA in the first direction DR1.

However, in FIG. 16, the gate insulating layer GISL may be shown as being formed on the entire surface of the first buffer layer BFF1 and the active pattern ACT, but is not limited thereto. For example, the gate insulating layer GISL may be formed to have the same width as the gate electrode GE through an etching process.

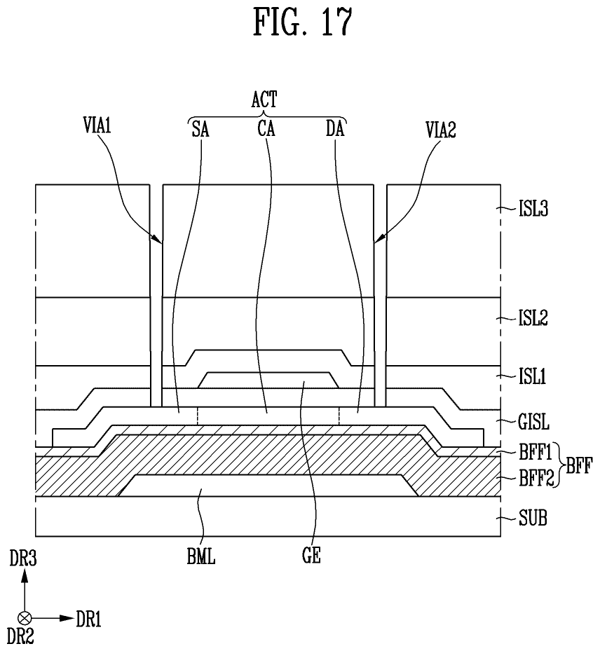

Referring to FIG. 17, the first to third insulating layers ISL1 to ISL3 may be sequentially formed on the gate insulating layer GISL and the gate electrode GE in the third direction DR3. The first to third insulating layers ISL1 to ISL3 may be formed by a deposition process such as sputtering, chemical vapor deposition (CVD), or plasma chemical vapor deposition (PECVD).

Thereafter, the first and second via holes VIA1 and VIA2 passing through the first to third insulating layers ISL1 to ISL3 may be formed. The first and second via holes VIA1 and VIA2 may be formed by selectively etching the first to third insulating layers ISL1 to ISL3 through a photolithography process. The first via hole VIA1 may be formed to expose a portion of the source area SA of the active pattern ACT. The second via hole VIA2 may be formed to expose a portion of the drain area DA of the active pattern ACT.

Referring to FIG. 18, the source electrode SE and the drain electrode DE may be formed on the first to third insulating layers ISL1 to ISL3. A conductive material filling the first and second via holes VIA1 and VIA2 may be deposited on the third insulating layer ISL3. Thereafter, the source electrode SE and the drain electrode DE may be formed by patterning the conductive material through a process of photolithography or the like. The source electrode SE may be formed to overlap the source area SA of the active pattern ACT, and the drain electrode DE may be formed to overlap the drain area DA of the active pattern ACT. The source electrode SE may be electrically connected to the source area SA through the first via hole VIA1. The drain electrode DE may be electrically connected to the drain area DA through the second via hole VIA2.

A display device according to an embodiment is applicable to various types of electronic devices. In an embodiment, an electronic device includes the above-described display device and may further include other modules or devices having additional functions in addition to the display device.

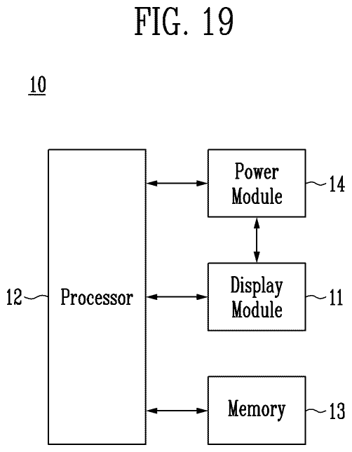

FIG. 19 is a schematic block diagram of an electronic device according to an embodiment. Referring to FIG. 19, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

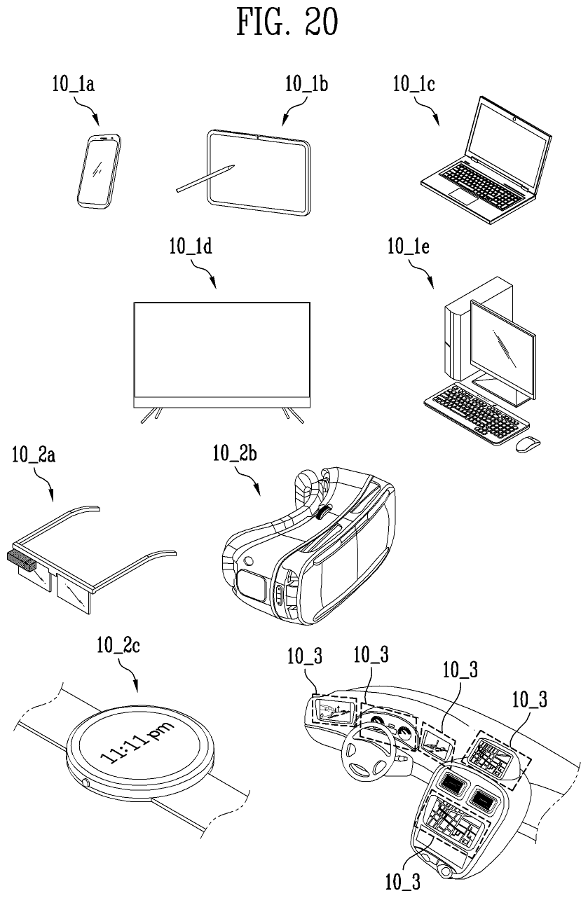

FIG. 20 shows schematic views of various embodiments of an electronic device.

Referring to FIG. 20, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

The thin film transistor included in the display device according to embodiments of the disclosure may include the first buffer layer including silicon oxide (SiOₓ) and the second buffer layer that does not include silicon oxide (SiOₓ) under the first buffer layer. For example, by forming the first buffer layer to be thin, a phenomenon in which a concentration of a threshold voltage moves in a negative direction as a channel length decreases may be prevented the driving voltage range (DR range) may be expanded. Accordingly, the thin film transistor included in the display device according to embodiments of the disclosure may cause a luminance difference of a grayscale image to be clearer by increasing a voltage difference between intermediate grayscale voltages, thereby improving display quality.

According to embodiments of the disclosure, a thin film transistor with improved quality and a method of manufacturing the same are provided.

According to other embodiments of the disclosure, a display device with improved quality is provided.

An effect according to embodiments is not limited to the content exemplified above, and further various effects are included in the present specification.

Although specific embodiments and application examples are described herein, other embodiments and modifications may be derived from the above description. Therefore, the spirit of the disclosure is not limited to such embodiments, and extends to the scope of the claims set forth below, various obvious modifications, and equivalents.

What is claimed is:

1. A thin film transistor included in a display device, the thin film transistor comprising:
buffer layers disposed on a substrate;
an active pattern disposed on the buffer layers;
a gate electrode disposed on the active pattern;
a gate insulating layer disposed between the active pattern and the gate electrode; and
a source electrode and a drain electrode electrically connected to the active pattern and spaced apart from each other in a first direction or a second direction crossing the first direction, wherein
the buffer layers include a first buffer layer contacting the active pattern and a second buffer layer disposed between the substrate and the first buffer layer,
the first buffer layer has a first thickness in a third direction perpendicular to the first and second directions,
the second buffer layer has a second thickness greater than the first thickness in the third direction,
the first buffer layer includes silicon oxide (SiOₓ), and
the second buffer layer does not include the silicon oxide.

2. The thin film transistor of claim 1, wherein the first thickness is about 100 nm or less.

3. The thin film transistor of claim 1, wherein the second buffer layer includes silicon nitride (SiNₓ).

4. The thin film transistor of claim 1, wherein the second buffer layer has a dielectric constant of about 6 or more.

5. The thin film transistor of claim 1, wherein the buffer layers have a first capacitance per unit area,
the gate insulating layer has a second capacitance per unit area, and
the first capacitance is about 60% or more of the second capacitance.

6. The thin film transistor of claim 1, wherein the buffer layers have a first capacitance per unit area, and
the first capacitance is about 1.7×10⁻⁸ F/cm² or more.

7. The thin film transistor of claim 1, further comprising:
a lower conductive layer disposed on the substrate and overlapping the active pattern,
wherein a sum of the first thickness and the second thickness is more than about ½ of a thickness of the lower conductive layer.

8. The thin film transistor of claim 7, wherein the first thickness of the first buffer layer is less than about ⅓ of the thickness of the lower conductive layer.

9. The thin film transistor of claim 1, wherein the buffer layers further include a third buffer layer disposed between the substrate and the second buffer layer.

10. The thin film transistor of claim 1, wherein the first buffer layer has a lower surface contacting the second buffer layer and an upper surface opposite to the lower surface and contacting the active pattern, and
the upper surface of the first buffer layer and the active pattern have a same width.

11. The thin film transistor of claim 1, further comprising:
a plurality of insulating layers disposed on the gate electrode,
wherein the source electrode and the drain electrode are disposed in a same layer on the plurality of insulating layers.

12. The thin film transistor of claim 11, wherein the active pattern includes a source area, a drain area, and a channel area disposed between the source area and the drain area,
the source electrode is electrically connected to the source area, and
the drain electrode is electrically connected to the drain area.

13. The thin film transistor of claim 12, further comprising:
a lower conductive layer disposed on the substrate and overlapping the active pattern,
wherein the lower conductive layer and the source electrode are electrically connected to each other to have a same voltage.

14. A display device comprising:
a display element; and
a thin film transistor providing a driving signal to the display element,
wherein the thin film transistor includes:
buffer layers disposed on a substrate;
an active pattern disposed on the buffer layers;
a gate electrode disposed on the active pattern;
a gate insulating layer disposed between the active pattern and the gate electrode; and
a source electrode and a drain electrode electrically connected to the active pattern and spaced apart from each other
in a first direction or a second direction crossing the first direction,
the buffer layers include a first buffer layer contacting the active pattern and a second buffer layer disposed between the substrate and the first buffer layer,
the first buffer layer has a first thickness in a third direction perpendicular to the first and second directions,
the second buffer layer has a second thickness greater than the first thickness in the third direction,
the first buffer layer includes silicon oxide (SiOₓ), and
the second buffer layer does not include the silicon oxide.

15. The display device of claim 14, wherein the first thickness is about 100 nm or less.

16. The display device of claim 14, wherein the second buffer layer includes silicon nitride (SiNₓ).

17. The display device of claim 14, wherein the display element includes:
an anode electrode connected to the thin film transistor;
a light emitting layer disposed on the anode electrode; and
a cathode electrode disposed on the light emitting layer disposed between the cathode electrode and the anode electrode.

18. An electronic device comprising:
a processor to provide input image data; and
a display device to display an image based on the input image data, the display device including a thin film transistor,
wherein the thin film transistor comprises:
buffer layers disposed on a substrate;
an active pattern disposed on the buffer layers;
a gate electrode disposed on the active pattern;
a gate insulating layer disposed between the active pattern and the gate electrode; and
a source electrode and a drain electrode electrically connected to the active pattern and spaced apart from each other in a first direction or a second direction crossing the first direction,
wherein
the buffer layers include a first buffer layer contacting the active pattern and a second buffer layer disposed between the substrate and the first buffer layer,
the first buffer layer has a first thickness in a third direction perpendicular to the first and second directions,
the second buffer layer has a second thickness greater than the first thickness in the third direction,
the first buffer layer includes silicon oxide (SiOx), and
the second buffer layer does not include the silicon oxide.
